(19) United States
(12) Patent Application Publication
(10) Pub. No.: US 2003/0183268 A1
(43) Pub. Date: Oct. 2, 2003

(54) Device for conversion of environmental thermal energy into direct current electricity

(76) Inventor: Daniel Jay Shanefield, Princeton, NJ (US)

Correspondence Address: Daniel J. Shanefield, 119 Jefferson Road, Princeton, NJ, 08540-3373, US

(21) Appl. No.: 10/112,655

(22) Filed: Mar. 29, 2002

(51) Int. Cl. H01L 35/30; H01L 35/02

(52) U.S. Cl. 136/205; 136/242

(57) ABSTRACT

Nearly-random electron motion in the primary wire of a transformer is amplified by that transformer, and the varying peaks of voltage drive some current pulses through a rectifying diode. These pulses charge a capacitor, and that charge can provide electrical energy through output wires, to do useful work elsewhere.

### TECHNICAL FIELD

1. The present invention relates to energy conversion devices, and in particular, to a specific device that converts nearly random thermal energy from the ambient environment into direct current electricity.

### BACKGROUND OF THE NVENTION

2. Many types of energy conversion devices are known, a common example being a thermocouple, and another example being a photovoltaic semiconductor diode (solar cell). These each depend on an energy source, such as a mass of material at a higher temperature than the temperature of the ambient environment, or a source of fairly high energy light rays. However, these energy sources are not always available.

3. It is known that even the ambient environmental energy from a mass of material at “room temperature” is sufficient to emit small pulses of electricity into wires that are attached. These pulses are nearly random in voltage and timing, and they are usually considered to be “electrical noise.” Such energy is widely available, but it is not intense. For example, low energy electrrical pulses are emitted from the electronic components called resistors. Some of these pulses have a lot more voltage than others. The effective voltage that is used to calculate the wattage of power (similar to an average, but not quite the same) is called the root mean square, or RMS voltage. This RMS value is approximately 0.002 volts for a typical resistor at 17 degrees Centigrade, according to the page 134 of the chapter by B. M. Oliver, in the book “Electrical Noise,” edited by Madhu S. Gupta (IEEE Press, New York, 1977). This voltage is so small, that if it were directed toward a potentially useful device such as a resistive heating element or an electric motor, that device's own emitted RMS voltage would oppose it during many periods of the time, and no practical use would be likely. Some method of accumulating the electricity would have to be invented, so that larger amounts of it could become available, at least for limited periods of time.

4. If the nearly random emitted pulses of electricity could be rectified into the form of direct current (dc), then these coulombs of charge could be accumulated in a capacitor (condenser), over a long period of time, and then that larger amount of electricity could become usable for heating, running a low power motor, etc., at least for limited periods of time. Several capacitors could be switched into a series configuration, and groups of these could later be switched into a parallel configuration, providing much more electrical power, at least for limited periods of time. However, a difficulty with this approach is that rectifying semiconductor diodes (such as P-type/N-type or PN junctions) require a certain minimum voltage (called the forward voltage drop), in order to pass fairly large currents. For example, a typical silicon PN diode requires approximately 0.6 volts to pass 1 milliampere, as described by D. J. Shanefield, on page 153 of his textbook, “Industrial Electronics for Engineers, Chemists, and Technicians” (William Andrew Publishing, Norwich, N.Y., 2001). Some other rectifiers such as germanium PN or Schottky metal/semiconductor types have lower voltage requirements, as described on the same page of the same literature reference, but these still need much more than the 2 millivolt RMS that would be available from the noise pulses from a resistor at room temperature.

5. An electrical transformer might possibly be used to increase the available voltage of noise pulses. (Transformers are explained on page 105 of the textbook by Shanefield, cited above.) The higher voltages might be imagined to go through a rectifying diode and then be accumulated in a capacitor, for later practical usage. However, the noise pulses tend to be of high frequency, and most transformers are inefficient at high frequencies, because of eddy current losses. Also, most transformers only increase the voltage by factors of 10 or less, and the resulting accumulated power in the capacitor might be imagined to be of only negligible practical use.

### SUMMARY OF THE INVENTION

6. The object of this invention is to provide useful direct current electricity that is generated from the ambient environmental heat present in air, liquid, or solid that is in contact with the novel device.

7. The present invention provides the combination of a low loss electrical transformer, a rectifying semiconductor diode with low leakage current in the reverse direction, and a capacitor to accumulate direct current pulses in the form of useful electric charge. This combination is a novel device that generates electricity from the energy present in ambient envirornmental heat.

8. The advantage of this invention over prior art is that useful direct current electricity can be generated without the need for energy sources such as batteries, light, etc.

### 9. LIST OF DRAWINGS

FIG. 1. Electrical Circuit Diagram

### DETAILED DESCRIPTION

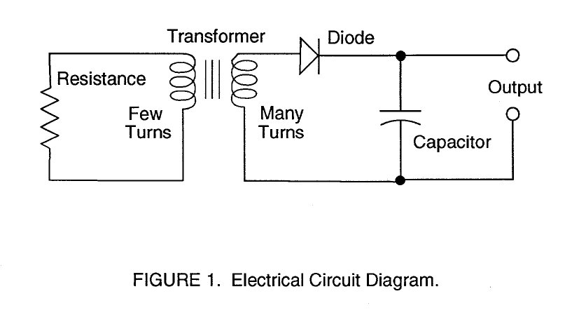

10. The present invention comprises the combination of a transformer having a core with a low eddy current loss, and a rectifying diode having low reverse leakage current, and a capacitor to accumulate the electric charge, as shown in the drawing of FIG. 1. The resistor attached across the primary coil of the transformer is desirable, but it is not necessary. (This will be explained below.) It is desirable but not necessary that the transfomer have at least 100 times more turns in the secondary coil than in the primary coil.

11. Transformers with ferrite ceramic cores (instead of iron cores) can be efficient for high frequency use, especially if they are designed to have high permeability and low eddy current loss (described further on pages 105, 114 and 268 of the textbook by Shanefield, cited above). It was found during experiments that an inexpensive transformer can be made with low loss and high permeability, which also has a 200 to 1 increase in voltage output (step up). The core material was manganese zinc ferrite (FR-33 ceramic rod, from Ocean State Electronics Corp., Westerly, R.I.). A winding comsisting of only a single turn of enameled 30 gauge copper wire in the primary coil was used, and the inventor was surprised to find that this produced sufficient electromagnetic field to provide a useful output in the secondary coil consisting of 200 turns of the same type of wire. (A variety of other coils and turns ratios were tried, and many also had usable results.)

12. To the surprise of the inventor, a germanium PN rectifying diode and a Schottky (metal/silicon) rectifying diode did not give good results when they were tried instead of the silicon PN diode in the diagram. The reason was that, even though the forward voltage drops were low, the leakage currents in the reverse direction (going back into the transformer secondary coil) were too high, and useful charges did not accumulate in the capacitor. Possibly germanium or Schottky silicon diodes of better quality could give good results, but instead a silicon PN diode with a 400 volt peak inverse voltage (PIV) was tried. This diode had a reverse current that was too low to be measured by equipment available to the inventor, and it was low enough so that useful charge did accumulate in the capacitor shown in the drawing of FIG. 1.

13. Another factor which can make a silicon PN diode useful for rectifying noise pulses is that very small minumum voltages can go forward through the diode, whenever currents smaller than 1 milliampere are involved. In fact, at extremely low currents, the forward voltage drop is also extremely small, and moderately strong random noise pulses can pass through, to charge a capacitor. Therefore a silicon PN diode was found to be better in the circuit of the present invention than germanium or Schottky diodes, although this might not be true of different specimens.

14. In one experiment performed by the inventor, a 5,700 ohm resistor was used as the resistor in the diagram. The resistor was of the “carbon composition” type, made from graphite particles mixed with clay and covered with epoxy insulation, with a tolerance rating of ±10%. The output terminals shown in the diagram were attached to a digital voltmeter (Model 860 GMM, Fluke Corp., Everett, Wash.). This meter has an input resistance too high to be measured by equipment available to the inventor, and therefore very little electricity was wasted by passing into the meter. The transformer being used in the experiment is described in paragraph 11 above, with a 200:1 step up voltage ratio. A silicon diode having a 400 volt PIV was used, feeding dc current into a 1 microfarad capacitor made out of metallized polypropylene film. Typical voltages accumulated in the capacitor were approximately 0.02 volts, but these varied greatly with temperature. Because heat was drawn from the resistor, it became cooled, and the voltage measured by the meter became lower during approximately 5 minutes in the ambient room air, which was at 21 degrees Celsius. Warming the resistor with artificially heated air raised the accumulated voltage to 0.3 volts, and cooling with refrigerated air lowered the voltage to 0.0004 volts. In each of the experiments reported here, the entire apparatus (including the meter) was enclosed in copper metal screen or alumunum metal boxes, all attached to a water pipe ground connection, in order to isolate the circuits from electromagnetic fields.

15. Because of the need to bring heat into the central parts of the resistor, a better resistor was found to be a thick film composition of fired cermet, as described on page 284 of the chapter by Daniel J. Shanefield, entitled “Electronic Thick Film Technology,” in the book entitled “Ceramic Films and Coatings,” edited by J. W. Wachtman and R. A. Haber, Noyes Publications, Park Ridge, N.J., 1993. When such a resistor film is made on an aluminum oxide (alumina) supporting substrate, the thermal conductivity of the overall composite is quite high, typically 25 watts per degree Kelvin per meter (as listed on page 291 of that same Wachtman and Haber book). In ambient, unheated air, the voltage obtained with the circuit of the present invention remained at approximately 0.06 volt, and it did not decrease with time to about 0.02 volt, as it did when the carbon composition resistor was used. When a 6,000 ohm thick film resistor on an aluminum nitride supporting substrate was used instead of the alumina material, the voltage remained at approximately 0.1 volt in ambient air at 21° C. This was probably due to the high thermal conductivity of aluminum nitride material, which is reported to be approximately 200 watts/Km on page 291 of the Wachtman and Haber book cited above. In general, better electricity generation was found to be obtainable when resistors were intimately bonded to heat conducting ceramic plus copper metal composites such as described in U.S. Pat. No. 3,679,472 by D. J. Shanefield and G. E. Crosby (1972). Approximately 0.1 volt or higher was obtainable with such composites.

16. To the surprise of the inventor, aproximately 0.005 volt of output was accumulated in the capacitor when the above experiment was repeated with no resistor attached to the primary coil, either with an open circuit as the primary input, or with a short circuit as the primary input. Evidently, electrons in the primary coil move randomly at room temperature, making enough magnetic field to generate a voltage output from the secondary coil, and therefore a useful voltage passes through the diode and into the capacitor. However, when an inductor was wound the same way as the secondary winding of the transformer described above (200 turns, on a ferrite rod core), but with no primary coil, the output of the present invention (minus the primary coil) was negligible (less than 0.001 volt). That proved that a transformer with two coils is necessary. However, two-coil transformers with step-up ratios as low as 10:1 did produce output voltages as high as 0.02 volt.

17. In another variation of the same basic experiment described above, two circuits such as are described by FIG. 1 were assembled, and the outputs were connected in series. The total voltage was twice that of either alone. In another variation of the same basic experiment described above, two such circuits were connected in parallel, and when a 1 megohm resistor was connected across the combined output terminals, the voltage decreased more slowly than with one such circuit, showing that more coulombs of charge were being accumulated. In still another experiment, the single rectifying diode was replaced by a four-diode full wave rectifier bridge, as explained on page 157 of the electronics textbook by Shanefield, cited above. In that case, a 1 megohm resistor drained the capacitor more slowly than when a single diode was used. Voltage multiplier circuits with multiple diodes can also be used, as described in the textbook by Shanefield, cited above. Still other variations, modifications, and implementations of what is described herein will occur to those of ordinary skill in the art.

### DESCRIPTION OF THE PREFERRED EMBODIMENTS

18. A circuit as described in FIG. 1 above is assembled, with a 5,000 ohm resistor which is in intimate contact with a good conductor of heat, such as aluminum nitride ceramic, or another type of ceramic bonded on its back side to thick copper metal. The transformer has a core which is a closed cup or a closed toroid, made of ferrite ceramic that has a relative magnetic permeability of 1,000 or more, and a high electrical resistance of 100 ohm-centimeters or more. The ratio of secondary to primary coil turns is 100 or 188 more. A rectifying diode with an electrical resistance in the reverse direction of 100 megohms or more is used in the circuit, as shown in the diagram. A 1 microfarad metallized film capacitor with a de electrical resistance of 100 megohms or more is used. Only a load of resistance 1 megohm or more is attached to the output terminals, and only for a few seconds at a time.

19. The circuit of the previous embodiment example is assembled with a bridge rectifier made from four silicon diodes, instead of the single diode shown in the diagram.

20. The circuit of the previous embodiment example is assembled with a 1,000 mcrofarad electrolytic capacitor, instead of the single diode shown in the diagram.

21. The circuit of the previous embodiment example is assembled with a bridge rectifier made from four diodes, instead of the single diode shown in the diagram.

22. Multiple circuits of the kind decribed in the previous examples above are connected with their outputs in series, in order to increase the output voltage.

23. Circuits as described above but with different resistances can also be used, even with short circuited primary coils or with open circuited primaries, but output voltages might be lower than the ones cited above.

What i claim as my invention is:

1. An electrical circuit that converts heat energy into electricity, comprising:
a transformer having eddy current loss of less than 1% at more than 1 kiloHertz,
and with 1 or more turns of wire in the primary coil,
and with 10 or more turns of wire in the secondary coil,
which secondary coil is attached through a rectifying diode,
which diode has a reverse resistance of more than 10 megohms at 1 volt or less,
and the transformer secondary coil feeds electricity through the diode or a multiplicity of diodes into a capacitor to store the electricity that is generated,
and the capacitor has a dc resistance of more than 10 megohms at 1 volt or less.

2. The element of claim 1 wherein an electrical resistor is connected across said primary coil.

3. The element of claim 2 wherein said electrical resistor has a resistance of 100,000 ohms or less.

4. The element of claim 1 wherein said primary coil is not connected to anything (open circuit input).

5. The element of claim 1 wherein said primary coil input wires are short circuited to each other.

6. The element of claim 1 wherein complex rectifiers are used, such as a full wave bridge or a voltage multiplier arrangement of rectifier elements.

7. The element of claim 1 wherein the outputs of a mutiplicity of such circuits are connected together in series in order to increase the total output voltage.

8. The element of claim 1 wherein the outputs of a mutiplicity of such circuits are connected together in parallel in order to increase the total output current.
